(19) United States
(12) Patent Application Publication
(10) Pub. No.: US 2021/0055817 A1
(43) Pub. Date: Feb. 25, 2021

(54) ELECTRONIC DEVICE INCLUDING SENSOR AND MANUFACTURING METHOD THEREOF

(71) Applicant: Samsung Electronics Co., Ltd., Gyeonggi-do (KR)

(72) Inventors: Kwangho SHIN, Gyeonggi-do (KR); Jinman KIM, Gyeonggi-do (KR); Hyunsuk CHOI, Gyeonggi-do (KR)

(21) Appl. No.: 17/043,174

(22) PCT Filed: Jun. 7, 2019
(86) PCT No.: PCT/KR2019/006891

§ 371 Date: Sep. 29, 2020

(30) Foreign Application Priority Data
Jun. 12, 2018 (KR) 10-2018-0067767

(51) Int. Cl. G06F 3/041; H01L 27/32; H01L 51/52; H01L 51/56

(52) U.S. Cl. CPC G06F 3/0412; H01L 27/3244; H01L 27/323; H01L 27/3234; G06F 2203/04103; H01L 51/5253; H01L 51/56; H01L 2227/323; H01L 51/524

(57) ABSTRACT

Various embodiments of the present disclosure relate to an in-display electronic device in which a sensor is disposed inside a display, and a manufacturing method thereof. According to various embodiments of the present disclosure, provided is an electronic device, the electronic device comprising: a housing comprising a first plate and a second plate facing away from the first plate; a display panel disposed between the first plate and the second plate, wherein the panel is visible through the first plate and comprises a first surface facing in a first direction so as to face the first plate, and a second surface facing in a second direction opposite the first direction so as to face the second plate; at least one substrate layer disposed between the second surface and the second plate, wherein the substrate layer overlaps at least a portion of the panel when viewed from an upper surface of the first plate; a cushion layer disposed between the substrate layer and the second plate, wherein the cushion layer includes an opening which overlaps the panel when viewed from the upper surface of the first plate;
a first adhesive layer disposed between the second surface and the substrate layer, the first adhesive layer being contacted with the second surface and the substrate layer; a second adhesive layer disposed between the substrate layer and the cushion layer, the second adhesive layer being contacted with the substrate layer and the cushion layer;
a sensor disposed at at least a portion of the opening; and at least one through hole extending from the opening to the second surface through the second adhesive layer, the substrate layer, and the first adhesive layer. In addition, other various embodiments may be provided.

### TECHNICAL FIELD

The disclosure relates to an in-display electronic device having a sensor disposed inside a display and a method for manufacturing the same.

### BACKGROUND ART

A display device can both display images and perform a function of enabling a user to touch a displayed screen so as to input an electric graphic signal. Such a display device is usually used for a personal portable terminal, such as a laptop computer, an all-in-one PC, a tablet PC, a smartphone, or a portable multimedia player (PPM), for example. A display device may be equipped with a digitizer for a touch input. Unlike an input device such as a keyboard or a mouse, the digitizer refers to a device for receiving position information which is indicated by the user and input on the screen. Digitizers are commonly used to provide intuitive and convenient user interfaces.

### DETAILED DESCRIPTION OF THE INVENTION

### Technical Problem

According to some embodiments, A display used for an electronic device may be manufactured by stacking a display panel, an embossed portion, and a cushion. In order to minimize degradation of performance of an electronic device having an in-display structure, a sensor (for example, an ultrasonic fingerprint sensor) may be disposed at a close distance from cover glass. In such a structure, an opening needs to be formed in a cushion layer, and the sensor needs to be disposed through the opening and forced against an embossed layer.

After being stacked successively, the display panel, the embossed portion, and the cushion may be evenly consolidated/attached to each other through a lamination process and thus assembled into an “intermediate assembly” (hereinafter, referred to as a “laminated structure”), and cover glass, a sensor, and the like may be additionally coupled thereto, thereby completing the assembly. The lamination process includes a rolling process in which rollers are used, and the quality of consolidation/attachment of the assembly may be improved by warming/pressurizing the laminated structure during the rolling process. However, insufficient pressurizing force may be delivered to a space formed by the opening while a roller-based lamination process proceeds, and foam may accordingly remain between laminated layers, or the foam may be pushed to one side by the rollers and concentrated thereon, thereby increasing the foam density in a specific region.

Various embodiments disclosed in this document seek to provide, in connection with an in-display device including a sensor, an electronic device for efficiently removing foam and a method for removing foam thereby.

### Technical Solution

According to various embodiments disclosed in this document, there may be provide an electronic device including: a housing including a first plate and a second plate facing away from the first plate; a display panel disposed between the first plate and the second plate, the panel being visible through the first plate and including a first surface oriented in a first direction so as to face the first plate and a second surface oriented in a second direction opposite to the first direction so as to face the second plate; at least one substrate layer disposed between the second surface and the second plate, the substrate layer overlapping at least a part of the panel when viewed from an upper surface of the first plate; a cushion layer disposed between the substrate layer and the second plate, the cushion layer including an opening overlapping the panel when viewed from the upper surface of the first plate; a first adhesive layer disposed, so as to make contact, between the second surface and the substrate layer; a second adhesive layer disposed, so as to make contact, between the substrate layer and the cushion layer; a sensor disposed in at least a part of the opening; and at least one through-hole extending from the opening to the second surface via the second adhesive layer, the substrate layer, and the first adhesive layer.

According to various embodiments disclosed in this document, there may be provide an electronic device including: a housing including a first plate and a second plate facing away from the first plate; a touchscreen display panel disposed between the first plate and the second plate, the panel being visible through the first plate and including a first surface oriented in a first direction so as to face the first plate and a second surface oriented in a second direction opposite to the first direction so as to face the second plate; at least one substrate layer disposed between the second surface and the second plate, the substrate layer overlapping at least a part of the panel when viewed from an upper surface of the first plate; a cushion layer disposed between the substrate layer and the second plate, the cushion layer including a first opening overlapping the panel when viewed from the upper surface of the first plate; a first adhesive layer disposed, so as to make contact, between the second surface and the substrate layer; a second adhesive layer disposed, so as to make contact, between the substrate layer and the cushion layer, the second adhesive layer including a second opening overlapping the first opening when viewed from the upper surface of the first plate; a fingerprint sensor disposed in at least a part of the first opening; a third adhesive layer disposed, so as to make contact, between the substrate layer and the fingerprint sensor while filling at least a part of the second opening; and at least one through-hole extending from the second opening to the second surface via the substrate layer and the first adhesive layer.

According to various embodiments disclosed in this document, there may be provide a method for removing foam from a display panel of an electronic device, the method including the operations of: laminating a first protective layer having at least one through-hole formed therein on a display panel; laminating a second protective layer having an opening formed therein so as to provide a space for sensor seating on the first protective layer; inserting a foam prevention member into the opening and seating the foam prevention member on a surface of the first protective layer; attaching a release film to an upper portion of the second protective layer; compressing an upper portion of the release film by using a roller; and removing the release film and the foam prevention member.

### Advantageous Effects

Various embodiments disclosed in this document may be advantageous in that foam that may remain between a display panel and a protective layer of an in-display electronic device can be effectively removed.

Various embodiments disclosed in this document may be advantageous in that visibility of an in-display electronic device can be improved.

### BRIEF DESCRIPTION OF DRAWINGS

FIG. 1 is a front perspective view of a mobile electronic device according to an embodiment.

FIG. 2 is a rear perspective view of the electronic device in FIG. 1.

FIG. 3 is an exploded perspective view of the electronic device in FIG. 1.

FIG. 4 is a conceptual diagram illustrating the sectional structure of an electronic device according to various embodiments disclosed in this document.

FIG. 5 is a conceptual diagram illustrating the sectional structure of an electronic device according to embodiments different from the embodiments in FIG. 4.

FIG. 6 is a conceptual diagram illustrating the sectional structure of an electronic device according to other embodiments different from the embodiments in FIG. 4.

FIG. 7 is a diagram illustrating an electronic device according to various embodiments disclosed in this document, which has a panel, a first protective layer, and a second protective layer successively laminated from below.

FIG. 8A and FIG. 8B are diagrams schematically illustrating foam remaining before/after a rolling process according to various embodiments.

FIG. 9A and FIG. 9B are diagrams schematically illustrating foam remaining before/after a rolling process according to various embodiments disclosed in this document.

FIG. 10A and FIG. 10B are diagrams schematically illustrating sectional shapes of a foam occurrence region before/after a rolling process, in connection with a process of manufacturing an electronic device using a foam prevention member and a through-hole according to various embodiments disclosed in this document.

FIG. 11A and FIG. 11B are diagrams schematically illustrating sectional shapes of a foam occurrence region during vacuum compression, in connection with a process of manufacturing an electronic device using a foam prevention member and a through-hole according to various embodiments disclosed in this document.

FIG. 12 is a diagram illustrating the shape of a through-hole according to various embodiments disclosed in this document.

FIG. 13A is a schematic diagram illustrating impurities (for example, residues) occurring between a first protective layer and a second protective layer after a rolling process according to various embodiments disclosed in this document. FIG. 13B is a top view illustrating a through-hole according to an embodiment disclosed in this document. FIG. 13C is a top view illustrating a through-hole according to another embodiment disclosed in this document.

FIG. 14 is a flowchart of a method for manufacturing electronic device according to various embodiments disclosed in this document.

FIG. 15 is a block diagram of an electronic device inside a network environment according to various embodiments.

### MODE FOR CARRYING OUT THE INVENTION

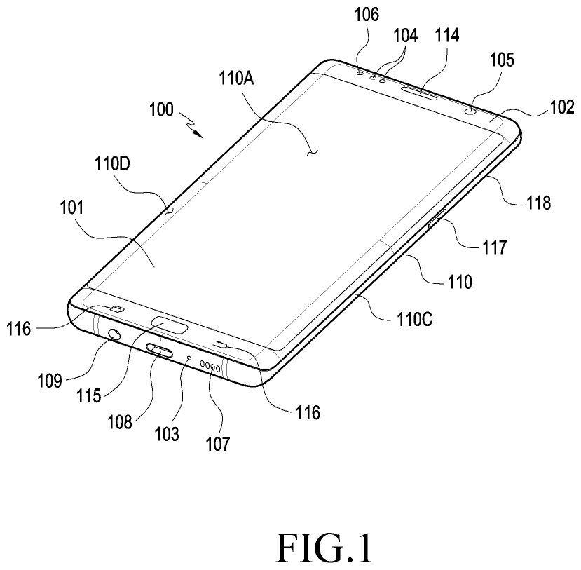

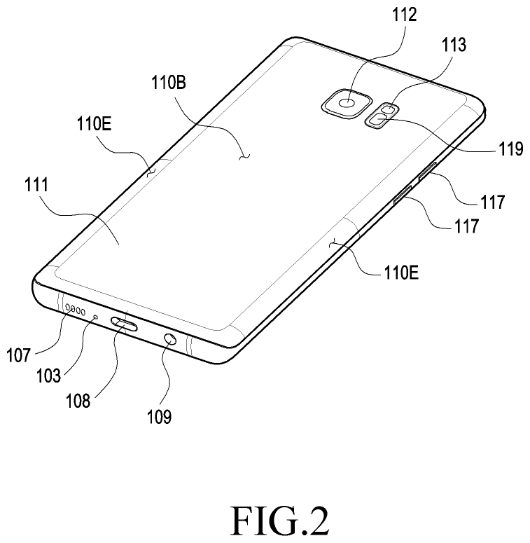

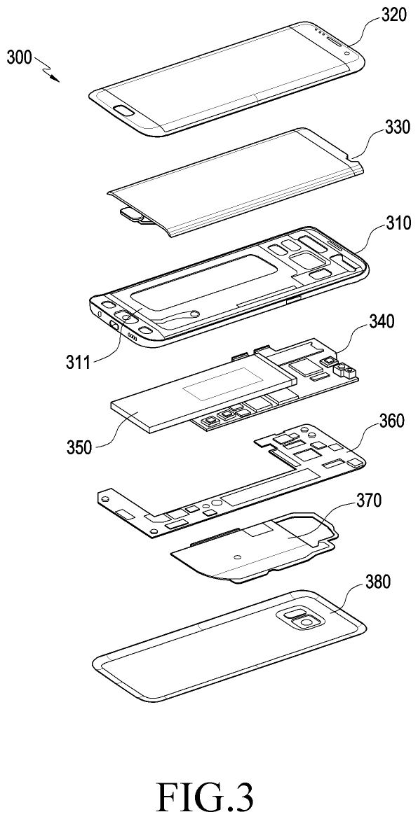

FIG. 1 is a front perspective view of a mobile electronic device according to an embodiment. FIG. 2 is a rear perspective view of the electronic device in FIG. 1. FIG. 3 is an exploded perspective view of the electronic device in FIG. 1.

Referring to FIG. 1 and FIG. 2, an electronic device 100 according to an embodiment may include a housing 110 including a first surface (or a front surface) 110A, a second surface (or a rear surface) 110B, and a side surface 110C surrounding the space between the first surface 110A and the second surface 110B. In another embodiment (not illustrated), the housing may refer to a structure forming at least some of the first surface 110A, the second surface 110B, and the side surface 110C in FIG. 1. According to an embodiment, the first surface 110A may be formed by a front plate 102, at least a part of which is substantially transparent (for example, a glass plate including various coating layers, or a polymer plate). The second surface 110B may be formed by a rear plate 111 which is substantially opaque. The rear plate 111 may be formed by, for example, coated or colored glass, ceramic, a polymer, a metal (for example, aluminum, stainless steel (STS), or magnesium), or a combination of at least two of the above materials. The side surface 110C may be formed by a side bezel structure (or “side member”) 118 which is coupled to the front plate 102 and the rear plate 111, and which includes a metal and/or a polymer. In some embodiments, the rear plate 111 and the side bezel structure 118 may be formed integrally and may include the same material (for example, a metal material such as aluminum).

In the illustrated embodiment, the front plate 102 may include two first regions 110D extending seamlessly so as to bend from the first surface 110A toward the rear plate 111, at both ends of a long edge of the front plate 102. In the illustrated embodiment (see FIG. 2), the rear plate 111 may include two second regions 110E extending seamlessly so as to bend from the second surface 110B toward the front plate 102, at both ends of a long edge thereof. In some embodiments, the front plate 102 (or the rear plate 111) may include only one of the first regions 110D (or the second regions 110E). In another embodiment, a part of the first regions 110D or the second regions 110E may not be included. In the above embodiments, when the electronic device 100 is seen laterally, a side surface of the side bezel structure 118, which does not include the above-mentioned first regions 110D or second regions 110E, may have a first thickness (or width), and another side surface thereof, which includes the above-mentioned first regions 110D or second regions 110E, may have a second thickness smaller than the first thickness.

According to an embodiment, the electronic device 100 may include at least one of a display 101, audio modules 103, 107, and 114, sensor modules 104 and 119, camera modules 105, 112, and 113, key input devices 115, 116, and 117, an indicator 106, and connector holes 108 and 109. In some embodiments, at least one of the components the electronic device 100 (for example, the key input devices 115, 116, and 117 or the indicator 106) may be omitted, or other components may be additionally included.

The display 101 may be seen through a corresponding part of the front plate 102, for example. In some embodiments, at least a part of the display 101 may be seen through the front plate 102 forming the first regions 110D of the side surface 110C, and the first surface 110A. The display 101 may be coupled to or disposed adjacent to a touch detection sensor, a pressure sensor capable of measuring the intensity (pressure) of a touch, and/or a digitizer configured to detect a magnetic-type stylus pen. In some embodiments, at least a part of the sensor modules 104 and 119 and/or at least a part of the key input devices 115, 116, and 117 may be disposed in the first regions 110D and/or the second regions 110E.

The audio modules 103, 107, and 114 may include a microphone hole 103 and speaker holes 107 and 114. The microphone hole 103 may have a microphone disposed therein so as to acquire external sounds. In some embodiments, multiple microphones may be disposed such that the direction of a sound can be sensed. The speaker holes 107 and 114 may include an external speaker hole 107 and a call receiver hole 114. In some embodiments, the speaker holes 107 and 114 and the microphone hole 103 may be implemented as a single hole, or a speaker may be included without the speaker holes 107 and 114 (for example, a piezoelectric speaker).

The sensor modules 104 and 119 may produce an electric signal or a data value corresponding to the operating state inside the electronic device 100 or the environment state outside the same. The sensor modules 104 and 119 may include, for example, a first sensor module 104 (for example, a proximity sensor) and/or a second sensor module (not illustrated) (for example, a fingerprint sensor) disposed on the first surface 110A of the housing 110, and/or a third sensor module 119 (for example, an HRM sensor) disposed on the second surface 110B of the housing 110. The fingerprint sensor may be disposed not only on the first surface 110A (for example, the home key button 115) of the housing 110, but also on the second surface 110B thereof. The electronic device 100 may further include a sensor module (not illustrated), for example, at least one of a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, or an illuminance sensor 104.

The camera modules 105, 112, and 113 may include a first camera device 105 disposed on the first surface 110A of the electronic device 100, and a second camera device 112 and/or a flash 113 disposed on the second surface 110B thereof. The camera devices 105 and 112 may include one lens or multiple lenses, an image sensor, and/or an image signal processor. The flash 113 may include, for example, a light-emitting diode or a xenon lamp. In some embodiments, two or more lenses (an infrared camera, wide-angle and telephoto lenses) and image sensors may be disposed on a surface of the electronic device 100.

The key input devices 115, 116, and 117 may include a home key button 115 disposed on the first surface 110A of the housing 110, a touch pad 116 disposed on the periphery of the home key button 115, and/or a side key button 117 disposed on the side surface 110C of the housing 110. In another embodiment, the electronic device 100 may not include some or all of the above-mentioned key input devices 115, 116, and 117, and the omitted key input devices 115, 116, and 117 may be implemented on the display 101 in other types (for example, soft keys).

The indicator 106 may be disposed on the first surface 110A of the housing 110, for example. The indicator 106 may provide state information of the electronic device 100, for example, in an optical type, and may include an LED.

The connector holes 108 and 109 may include a first connector hole 108 capable of containing a connector (for example, a USB connector) for transmitting/receiving power and/or data with an external electronic device, and/or a second connector hole (for example, an earphone jack) 109 capable of containing a connector for transmitting/receiving audio signals with the external electronic device.

Referring to FIG. 3, the electronic device 300 may include a side bezel structure 310, a first support member 311 (for example, a bracket), a front plate 320, a display 330, a printed circuit board 340, a battery 350, a second support member 360 (for example, a rear case), an antenna 370, and a rear plate 380. In some embodiments, at least one of the components of the electronic device 300 (for example, the first support member 311 or the second support member 360) may be omitted, or other components may be additionally included. At least one of the components of the electronic device 300 may be identical or similar to at least one of the components of the electronic device 100 in FIG. 1 or FIG. 2, and repeated descriptions thereof will be omitted herein.

The first support member 311 may be disposed inside the electronic device 300 and connected to the side bezel structure 310, or may be formed integrally with the side bezel structure 310. The first support member 311 may be made of a metal material and/or a nonmetal (for example, polymer) material, for example. The display 330 may be coupled to one surface of the first support member 311, and the printed circuit board 340 may be coupled to the other surface thereof. The printed circuit board 340 may have a processor, a memory, and/or an interface mounted thereon. The processor may include at least one of a central processing device, an application processor, a graphic processing device, an image signal processor, a sensor hub processor, or a communication processor, for example.

The memory may include a volatile memory or a nonvolatile memory, for example.

The interface may include, for example, a high-definition multimedia interface (HDMI), a universal serial bus (USB) interface, an SD card interface, and/or an audio interface. The interface may physically or electrically connect the electronic device 300 and an external electronic device, for example, and may include a USB connector, an SD card/MMC connector, or an audio connector.

The battery 350, which is a device for supplying power to at least one component of the electronic device 300, may include a primary batter which is not rechargeable, a secondary batter which is rechargeable, or a fuel cell, for example. At least a part of the battery 350 may be disposed on substantially the same plane with the printed circuit board 340, for example. The battery 350 may be disposed integrally inside the electronic device 300, or may be disposed such that the same can be attached to/detached from the electronic device 300.

The antenna 370 may be disposed between the rear plate 380 and the battery 350. The antenna 370 may include, for example, a near-field communication (NFC) antenna, a wireless charging antenna, and/or a magnetic secure transmission (MST) antenna. The antenna 370 may be used for short-range communication with an external device, for example, or may wirelessly transmit/receive power necessary for charging. In another embodiment, an antenna structure may be formed by a part or a combination of the side bezel structure 310 and/or the first support member 311.

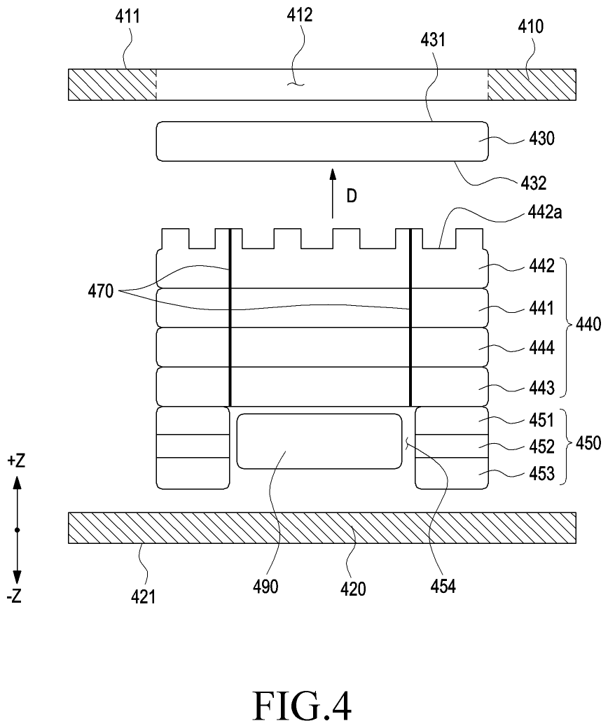

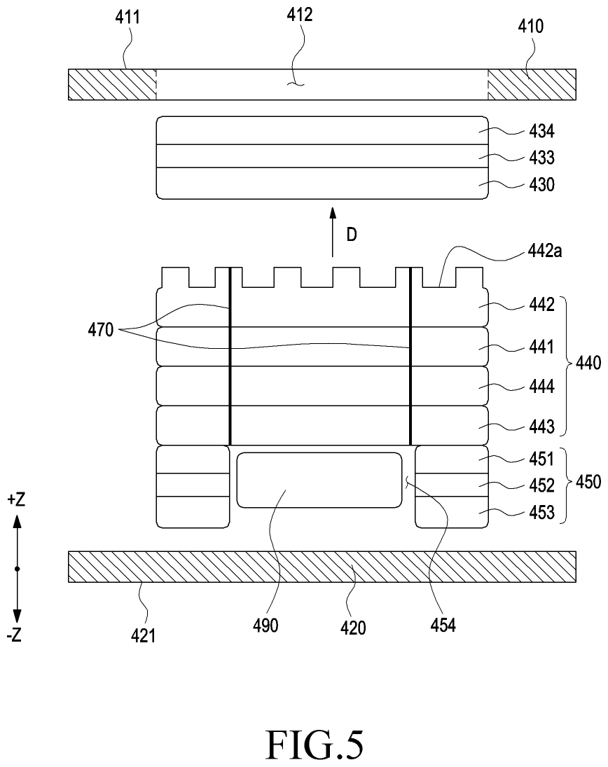

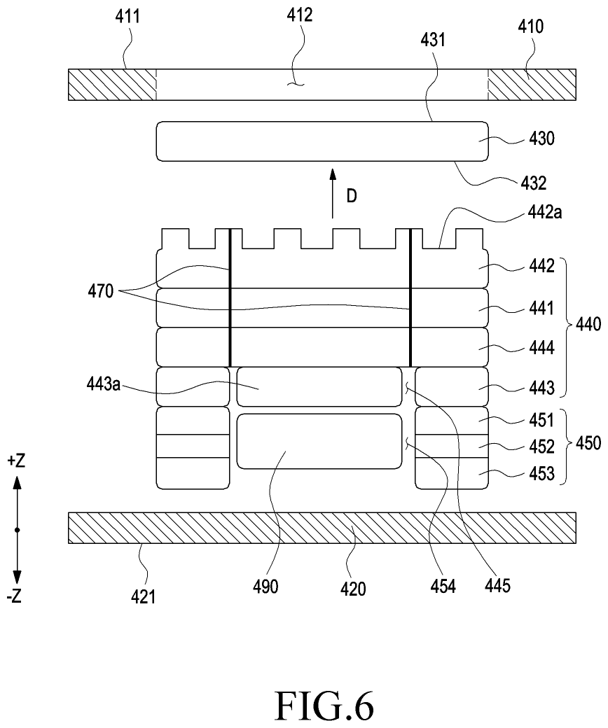

FIG. 4 is a conceptual diagram illustrating the sectional structure of an electronic device (for example, 100 in FIG. 1) according to various embodiments disclosed in this document. FIG. 5 is a conceptual diagram illustrating the sectional structure of an electronic device (for example, 100 in FIG. 1) according to embodiments different from the embodiments in FIG. 4. FIG. 6 is a conceptual diagram illustrating the sectional structure of an electronic device (for example, 100 in FIG. 1) according to other embodiments different from the embodiments in FIG. 4.

The sectional structure of an electronic device (for example, 100 in FIG. 1) illustrated in FIG. 4 to FIG. 6 may represent a diagram in which some of various components constituting the electronic device (for example, 100 in FIG. 1) illustrated in FIG. 1 to FIG. 3 are omitted. For example, the side bezel structure 118 illustrated in FIG. 1 (or the side bezel structure 310 illustrated in FIG. 3) may be omitted in the diagrams of FIG. 4 to FIG. 6.

Referring to FIG. 4, an electronic device (for example, 100 in FIG. 1) according to various embodiments disclosed in this document may include a housing including a first plate 410 and a second plate 420 facing away from the first plate 410. In addition, the electronic device may include a panel 430 disposed between the first plate 410 and the second plate 420. According to various embodiments, the front plate 102 and the rear plate 111 described above with reference to FIG. 1 may correspond to the first plate 410 and the second plate 420, respectively. In this case, the first plate 410 may include a portion 412, at least a part of which is substantially transparent. The first plate 410 may have an upper surface 411 facing in a first direction (for example, a direction parallel to direction component +z), and the second plate 420 may have a lower surface 421 facing in a second direction (for example, a direction parallel to direction component −z). According to an embodiment, at least a part of the panel 430 may be viewed from the outside through the upper surface 411 of the first plate 410.

According to various embodiments, the panel 430 may include a first surface 431 which faces the first plate 410 and faces in the first direction (for example, the direction parallel to direction component +z), and a second surface 432 which faces the second plate 420 and faces in the second direction (for example, the direction parallel to direction component −z) opposite to the first direction (for example, the direction parallel to direction component +z). The first surface 431 of the panel 430 may be disposed to abut the lower surface of the first plate 410, or at least a part of the panel 430 may be disposed to penetrate the lower surface of the first plate 410. According to such various embodiments, the panel 430 may be seen to the outside through the substantially transparent portion 412 of the first plate 410.

According to various embodiments, a touchscreen display panel may correspond to the panel 430. According to another embodiment, the panel 430 may correspond to a back panel of a display of an electronic device. When the panel 430 corresponds to a back panel, the panel 430 may be a component configured to protect other components (for example, an optical clear adhesive (OCA), a polarizer (POL), and an on-cell touch AMOLED (OCTA)) constituting a touchscreen display from impacts or to support the same on the housing.

Referring back to FIG. 4, a first protective layer 440 and a second protective layer 450, for example, may be disposed beneath the second surface 432 of the panel 430 according to various embodiments. According to an embodiment, the first protective layer 440 may overlap at least a part of the lower portion of the panel 430, and the second protective layer 450 may overlap at least a part of the lower portion of the first protective layer 440. Therefore, when viewed from the upper surface 411 of the first plate 410, the first protective layer 440 and the second protective layer 450 may be configured to successively overlap the panel 430. According to the embodiments illustrated in FIG. 4 to FIG. 6 of this document, each of the panel 430, the first protective layer 440, and the second protective layer 450 is illustrated as including multiple laminated layers, but this is not limiting in any manner. According to another embodiment, the first protective layer 440 and the second protective layer 450 may be combined and thus configured in an integrated manner. According to still another embodiment, the panel 430 as a back panel, the first protective layer 440, and the second protective layer 450 may be combined and configured in an integrated type.

It will be assumed in the following, for convenience of description, that the panel 430, the first protective layer 440, and the second protective layer 450 are separate components.

According to various embodiments, the first protective layer 440 may include at least one substrate layer 441 (or a transparent layer), a first adhesive layer 442, and/or a second adhesive layer 443. The substrate layer 441, which is disposed between the second surface 432 of the panel 430 and the second plate 420, may overlap at least a part of the panel 430 when viewed from the upper surface 411 of the first plate 410. The first adhesive layer 442 may be disposed between the second surface 432 of the panel 430 and the substrate 441 and may be configured to contact each of the second surface 432 and the substrate layer 441. The second adhesive layer 443 may be disposed between the substrate layer 441 and a cushion layer 451 and may be configured to contact each of the substrate layer 441 and the cushion layer 451.

Referring to FIG. 4, the first protective layer 440 may face the second surface 432 of the panel 430 and may be forced against the panel 430. The first protective layer 440 may have multiple embossed patterns 442a on a surface thereof, which is forced against the second surface 432 of the panel 430. By having the embossed patterns 442a, physical impacts applied to the electronic device may be absorbed, and it may become possible to reduce the amount of air that may remain on the surface of the first protective layer 440, which faces the panel 440, during a manufacturing process of attaching the protective layer 440 to the panel 430.

According to various embodiments, the embossed patterns 442a may be shaped such that a stepped shape is repeated multiple times, as illustrated in FIG. 4 to FIG. 6. Alternatively, the embossed patterns 442a may be formed in various other shapes, for example, in a streamlined shape in which a ridge portion and a valley portion are repeated.

According to various embodiments disclosed in this document, in connection with an electronic device having a sensor 490, a first protective layer 440 may be disposed between a panel 430 and the sensor 490 so as to support each of the panel 430 and the sensor 490, thereby improving the durability of the laminated structure thereof. For reference, the sensor 490 according to various embodiments disclosed in this document may be a biometric sensor such as a fingerprint sensor or an iris sensor. In addition, the sensor 490 may be a gesture sensor, a gyro sensor, an atmospheric pressure sensor, a magnetic sensor, an acceleration sensor, a grip sensor, a color sensor, an infrared (IR) sensor, a temperature sensor, a humidity sensor, or an illuminance sensor, besides the above-mentioned biometric sensor, or may be a camera module (for example, 105, 112, or 113 in FIG. 1) including an image sensor. According to various embodiments, any sensor configured such that, when disposed inside a display, the sensor mounting portion thereof or a part of the peripheral region thereof can be seen to the outside may be included in the sensor 490 according to various embodiments disclosed in this document.

According to various embodiments, the first protective layer 440 may include a substantially transparent first layer (for example, referred to as a “transparent layer”) and an opaque first layer 444 (hereinafter, referred to as an “opaque layer”). According to an embodiment, the substrate layer 441 may correspond to the transparent layer. According to an embodiment, the opaque layer 444 may be disposed between the first adhesive layer 442 and the second adhesive layer 443. According to an embodiment, the opaque layer 444 may be disposed between the first adhesive layer 442 and the substrate layer 44, and according to another embodiment, the opaque layer 444 may be disposed between the substrate layer 441 and the second adhesive layer 443.

According to various embodiments disclosed in this document, the second protective layer 450 may include a cushion layer 451, at least one adhesive layer 452, and a hear-radiating layer 453. The cushion layer 451 may be a member for absorbing physical impacts applied to the electronic device. According to an embodiment, the second protective layer 450 may be made of the same material as the first protective layer 440 or a different material from the first protective layer 440. According to an embodiment, by having the heat-radiating layer 453, the second protective layer 450 may effectively radiate heat produced by the panel 430. To this end, at least a part of the heat-radiating layer 453 may be made of a metal material. Referring to FIG. 4, the adhesive layer 452 included in the second protective layer 450 may be disposed between the cushion layer 451 and the heat-radiating layer 453 and configured to attach the cushion layer 451 and the heat-radiating layer 453 to each other.

According to various embodiments, the electronic device (for example, 100 in FIG. 1) may include an electromagnetic induction panel (for example, a digitizer). The electromagnetic induction panel may sense the approach of an electromagnetic inductor, such as a stylus pen. For example, the electromagnetic induction panel may be disposed between the first protective layer 440 and the heat-radiating layer 453.

The second protective layer 450 according to various embodiments disclosed in this document may include a first opening 454 provided to penetrate the second protective layer 450 while forming a space in which at least a part of the sensor 490 can be inserted/disposed. According to an embodiment, the first opening 454 may be connected from a surface of the second protective layer 454 (for example, the surface abutting the first protective layer 450) to the opposite surface of the second protective layer 450 (for example, the surface abutting the second plate 420) through the cushion layer 451, the adhesive layer 452, and the heat-radiating layer 453. According to various embodiments, the space formed by the first opening 454 may be formed to be larger than the horizontal and vertical widths of the sensor 490 when viewed from the upper surface of the first plate 410, and to be higher than the height of the sensor 490 when seen laterally as illustrated in FIG. 4.

According to various embodiments disclosed in this document, at least one through hole 470 may be included so as to extend from the first opening 454 to the second surface 432 of the panel 430 through the second adhesive layer 443, the substrate layer 441, and the first adhesive layer 442. According to an embodiment, the through-hole 470 may penetrate the entire first protective layer 440 as in the embodiment illustrated in FIG. 4. According to various embodiments, the through-hole 470 may have a cavity formed at the center thereof and, according to another embodiment, multiple micro ventilation holes (not illustrated) may be formed on the surface around the through-hole 470. When a cavity and ventilation holes are formed in the through-hole 470, air can freely flow in/out through the cavity and the ventilation holes, thereby discharging air remaining inside the first protective layer 440, for example, between the first protective layer 442 and the panel 430.

FIG. 5 and FIG. 6 illustrate an electronic device (for example, 100 in FIG. 1) according to an embodiment different from the embodiment in FIG. 4.

Referring to FIG. 5, an electronic device (for example, 100 in FIG. 1) according to various embodiments may further include a touch sensing layer 433 and a cover member 434 above a panel 430. The touch sensing layer 433 may be laminated on the first surface 431 of the panel 430, and the cover member 434 may be laminated above the touch sensing layer 433. In addition, various members may be laminated on the first surface 431 of the panel 430, and various members may be laminated beneath the second surface 432 of the panel 430.

Referring to FIG. 6, the electronic device (for example, 100 in FIG. 1) according to various embodiments may include a second adhesive layer 443 including a second opening 445 overlapping a first opening 454 when viewed from the upper surface 411 of the first plate 410. The second opening 445 may be provided for the same purpose as the first opening 454, and may have a larger width than the horizontal and vertical widths of the fingerprint sensor 490 when viewed from the upper surface of the first plate 410, as in the case of the first opening 454.

According to various embodiments, in an embodiment in which the second opening 445 is provided, a through-hole 470 may extend from the second opening 445 to the second surface 432 of the panel 430 through the substrate layer 441 and the first adhesive layer 442. That is, the embodiment in which the second opening 445 is provided may be advantageous, compared with the embodiment in which the first opening 454 is provided alone, in that the length of the through-hole 470 can be reduced.

According to various embodiments, a third adhesive layer 443a may be formed in the second opening 445, and the third adhesive layer 443a may be disposed between the substrate layer 441 and the sensor 490 so as to contact (or to be forced against) each of the substrate layer 441 and the sensor 490. Various embodiments may include an embodiment in which the second adhesive layer 443 is first attached to the panel 430, and the sensor 490 is attached and assembled to the other surface of the second adhesive layer 443 attached to the panel 430 through one surface thereof, and another embodiment in which, after attaching the sensor 490 to the second adhesive layer 443, the second adhesive layer 443 and the sensor 490 are together assembled to the panel 430. In the case of the former embodiment, a through-hole 470 may be formed so as to penetrate the entire first protective layer 440 including the second adhesive layer 443, thereby facilitating discharge of air remaining on the rear side of the panel 430. On the contrary, in the case of the latter embodiment, the through-hole 470 is formed before the second adhesive layer 443 is attached, and the sensor 490 is then attached. For this reason, air remaining on the rear side of the panel 430 may be blocked by the second adhesive layer 443 and thus may not be discharged easily. Therefore, in view of the case of the latter embodiment, an electronic device (for example, 100 in FIG. 1) according to an embodiment may include, as in the embodiment illustrated in FIG. 6, a second opening 445 formed in a predesignated position (for example, in a position corresponding to the through-hole 470), and a third adhesive layer 443a distinguished from the second adhesive layer 443 by the second opening 445.

As described above, the electronic device (for example, 100 in FIG. 1) according to the embodiments illustrated in FIG. 4 to FIG. 6 is advantageous in that, by having a through-hole 470, air remaining on the rear side (for example, the second surface 432) of the panel 430 can be effectively discharged to the outside during electronic device manufacturing processes.

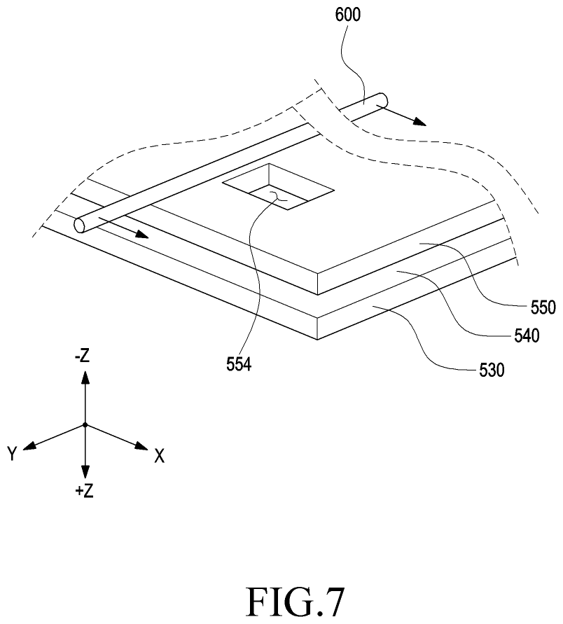

Hereinafter, a method for removing foam in connection with an electronic device (for example, 100 in FIG. 1) for residual air prevention according to various embodiments may be described with reference to FIG. 7 to FIG. 14. In the embodiments illustrated in FIG. 7 to FIG. 14, components of the display may be illustrated in simpler forms. For example, the substrate layer (for example, 441 in FIG. 4), the first adhesive layer (for example, 442 in FIG. 4), and the second adhesive layer (for example, 443 in FIG. 4) may be simply illustrated as a first protective layer 540 (for example, 440 in FIG. 4), and the cushion layer (for example, 451 in FIG. 4), the adhesive layer (for example, 452 in FIG. 4), and the heat-radiating layer (for example, 453 in FIG. 4) may be simply illustrated as a second protective layer 550 (for example, 450 in FIG. 4). In addition, detailed components mentioned in the above-described embodiments may be described as components included in the first protective layer 540 or the second protective layer 550.

FIG. 7 is a diagram illustrating an electronic device (for example, 100 in FIG. 1) according to various embodiments disclosed in this document, which has a panel 530, a first protective layer 540, and a second protective layer 550 successively laminated from below. With reference to the coordinate-axis directional components in FIG. 7, components included in the electronic device are illustrated as being laminated in the opposite direction to the section in FIG. 4.

As illustrated in FIG. 7, the display may have a panel 530, a first protective layer 540, and a second protective layer 550 laminated on each other. The pane 530, the first protective layer 540, and the second protective layer 550, laminated on each other, may be referred to as an “intermediate assembly” (hereinafter, referred to as a “laminated structure”). In addition, the laminated structure may be turned into a “complete assembly” through coupling with other components such as a sensor (for example, 490 in FIG. 4) and a cover member (for example, 434 in FIG. 5). The second protective layer 550 may have a first opening 554 (for example, 454 in FIG. 4) formed therein such that a sensor (for example, 490 in FIG. 4) is disposed therein. By providing the first opening 554, and by disposing a sensor (for example, 490 in FIG. 4) therein, performance degradation in the in-display structure may be minimized. A first protective layer 540 and a second protective layer 550 are laminated on the panel 530, and a rolling process (or lamination process) using a roller 600 may be performed to this end. The roller 600 may play the role of pressing the second protective layer 550 so as to pressurize the first protective layer 540 in a state in which the panel 530, the first protective layer 540, and the second protective layer 550 are successively laminated. Through the rolling process, the second protective layer 550 comes to press the first protective layer 540 at a designated temperature and a designated pressure, and the first protective layer 540 may accordingly be evenly forced against the panel 530.

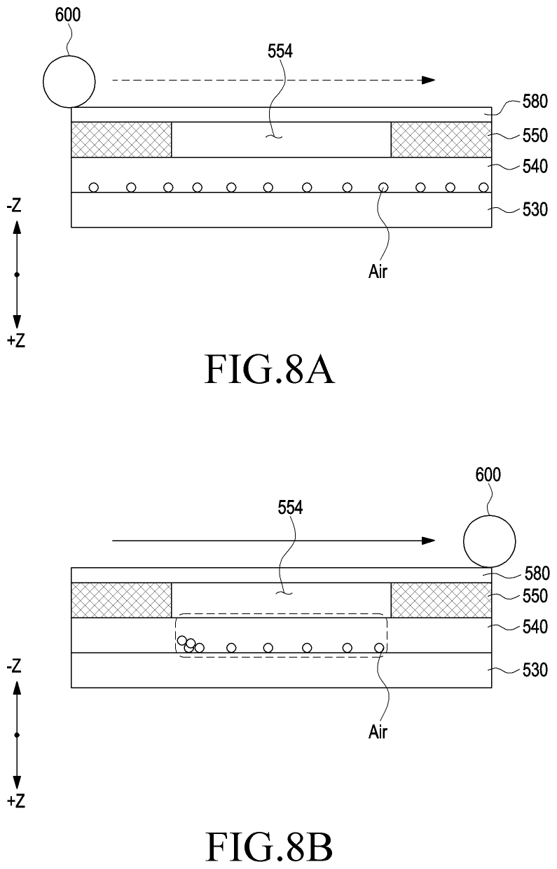

FIG. 8A and FIG. 8B are diagrams schematically illustrating air remaining before/after a rolling process according to various embodiments. FIG. 8A may illustrate a state before the rolling process, and FIG. 8B may illustrate a state after the rolling process.

FIG. 8A illustrates a rolling process performed in a state in which a first opening 554 is formed in the laminated structure, and in which a release film 580 (mold-releasing sheet or peeling sheet) (hereinafter, referred to as a “mold-releasing sheet”) is laminated thereon. The mold-releasing sheet 580 refers to a component which can be used during a process of compressing the first protective layer 540 by using a roller 600, and which may be removed after the first protective layer 540 is compressed. Referring to the above-described embodiments in FIG. 4 to FIG. 6 together, in the course of assembling the first protective layer 540 to the panel 530 along directional component D (for example, D in FIG. 4), foam may not be removed and may thus remain between the first protective layer 540 and the panel 530. Before the rolling process, as in the embodiment illustrated in FIG. 8A, foam may be widely distributed along facing surfaces of the first protective layer 540 and the panel 530. After the rolling process, as in the embodiment illustrated in FIG. 8B, foam may be removed as the first protective layer 540 is pressurized by the roller 600 in a region of the facing surfaces of the first protective layer 540 and the panel 530, in which the second protective layer 550 is laminated, but the foam may not be removed and thus may remain in a region in which the second protective layer 550 is not laminated because no pressurizing force is delivered from the roller 600 to the first protective layer 540. According to some embodiments, foam in the region of the facing surfaces of the first protective layer 540 and the panel 530, in which the second protective layer 550 is laminated, may be pushed and moved into the region in which the second protective layer 550 is not laminated, thereby increasing the density of remaining foam in some regions as illustrated in FIG. 8B. This may result in a different in reflectivity between the region in which foam exists and the region no foam exists, and may cause a visibility problem in that, when the user views the display, the foam region can be seen. Moreover, the existence of foam may result in a difference in the modulus of the material, thereby degrading the performance of the display.

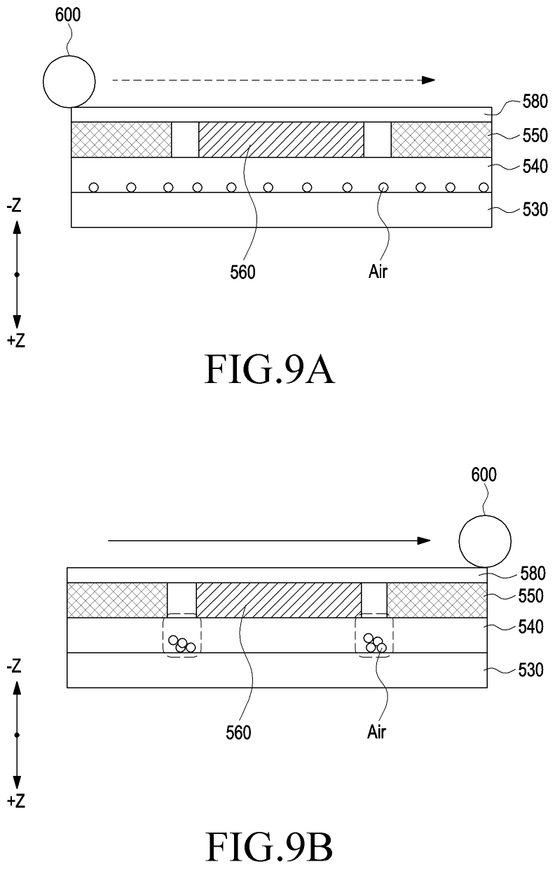

FIG. 9A and FIG. 9B are diagrams schematically illustrating foam remaining before/after a rolling process according to various embodiments disclosed in this document. FIG. 9A may illustrate a state before the rolling process, and FIG. 9B may illustrate a state after the rolling process. Unlike FIG. 8, FIG. 9 illustrates a provided foam prevention member 560.

According to various embodiments, the foam prevention member 560 may be disposed in a first opening (for example, 554 in FIG. 8) and positioned between a first protective layer 540 and a mold-releasing sheet 580. The foam prevention member 560 may be a structure which is used before the first protective layer 540 is compressed, prior to the rolling process, and which can be removed together with the mold-releasing sheet 580 after the first protective layer 540 is compressed through the rolling process. The foam prevention member 560, which can deliver a pressurizing force from a roller 600 to the first protective layer 540 during compression using the roller 600, may be made of a hard material, such as synthetic resin, according to an embodiment. The foam prevention member 560 may be made of the same material as the second protective layer 550 according to another embodiment.

Referring to FIG. 9A and FIG. 9B together, the embodiment in which the foam prevention member 560 is provided is advantageous in that foam widely distributed between the panel 530 and the first protective layer 540 before the rolling process is concentrated in a narrower region after the rolling process than in the case of the embodiment illustrated in FIG. 8B. The pressurizing force during the rolling process is better delivered to the first protective layer 540 by the foam prevention member 560 such that foam can be removed from the region in which the foam prevention member 560 and the first protective layer 540 are laminated on each other. That is, the embodiment illustrated in FIG. 9 may be advantageous in that foam is removed from facing surfaces of the panel 530 and the first protective layer 540, except for the region in which the second protective layer 550 or the foam prevention member 560 does not exist (offset region). The offset region may be formed around the foam prevention member 560 inside the first protective layer 540.

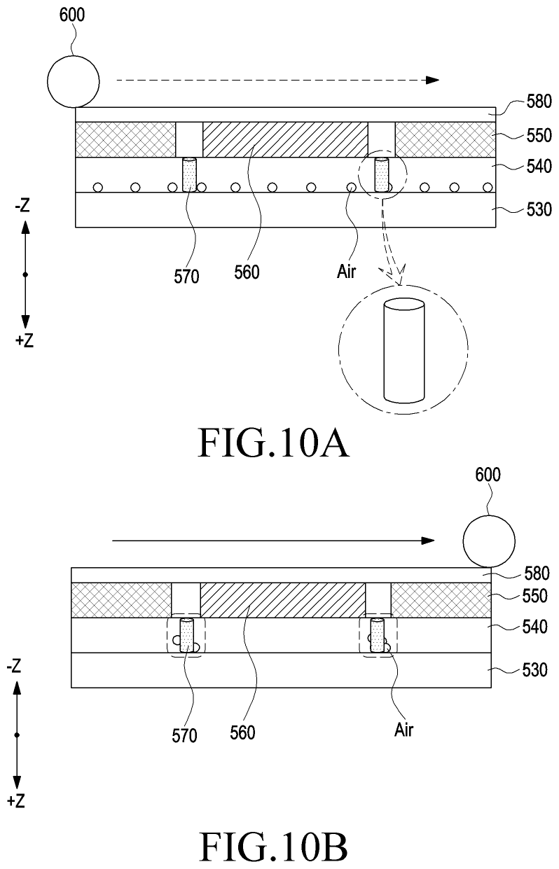

FIG. 10A and FIG. 10B are diagrams schematically illustrating sectional shapes of a foam occurrence region before/after a rolling process, in connection with a process of manufacturing an electronic device (for example, 100 in FIG. 1) having a foam prevention member 560 and a through-hole 570 according to various embodiments disclosed in this document. FIG. 10A may illustrate a shape before the rolling process, and FIG. 10B may illustrate a shape after the rolling process. Unlike FIG. 9, FIG. 10 illustrates an additionally provided through-hole 570.

It may be inferred that, according to the embodiments illustrated in FIG. 9A and FIG. 9B, the region in which foam may remain can be reduced by manufacturing an electronic device (for example, 100 in FIG. 1) by using the foam prevention member 560, and the visibility problem can be partially improved thereby.

According to the embodiments illustrated in FIG. 10A and FIG. 10B, by additionally providing a through-hole 570 besides the foam prevention member 560, foam remaining in the offset region inside the first protective layer 540 can also be removed. The through-hole 570 may be formed in at least a part of the offset region of the first protective layer 540. The through-hole 570 may extend from a surface of the panel 530 (for example, the second surface 432 in FIG. 4) to the first opening (for example, 545 in FIG. 8). The through-hole 570 may be formed by punching or drilling the first protective layer 540 itself according to an embodiment, or may be formed by inserting a tube-shaped body, which is made of the same material as the first protective layer 540 or a material different therefrom, into the first protective layer 540 according to another embodiment.

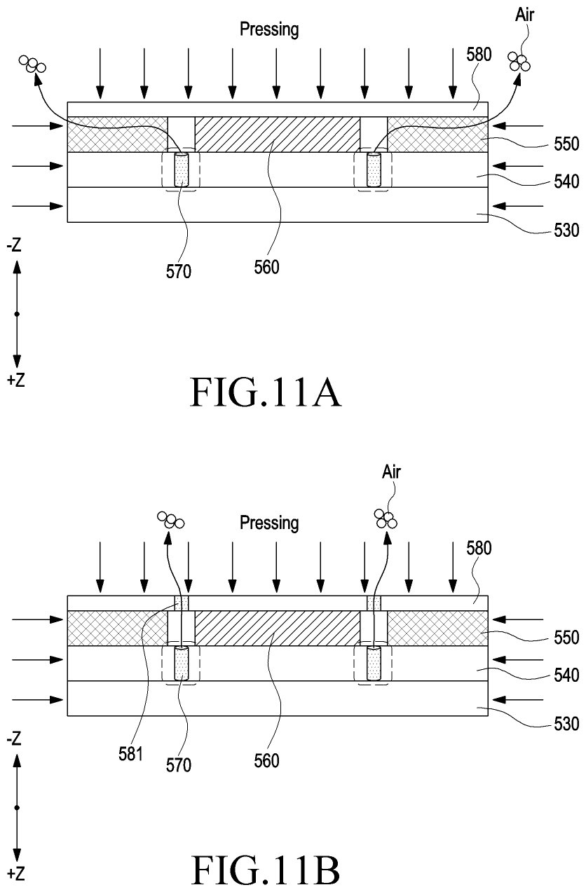

FIG. 11A and FIG. 11B are diagrams schematically illustrating sectional shapes of a foam occurrence region during vacuum compression, in connection with a process of manufacturing an electronic device (for example, 100 in FIG. 1) using a foam prevention member 560 and a through-hole 570 according to various embodiments disclosed in this document. FIG. 11A may illustrate a shape during vacuum compression in a state in which a foam prevention member 560 and a through-hole 570 are provided, and FIG. 11B may illustrate a shape during vacuum compression in a state in which a second through-hole 581 is added to FIG. 11A.

In connection with an electronic device manufacturing process, a vacuum compression process (for example, autoclave) may be conducted after a rolling process is performed, thereby removing remaining foam.

As in the embodiment illustrated in FIG. 11A, if a vacuum compression process is performed in a state in which a foam prevention member 560 and a through-hole 570 are solely provided, foam may be discharged while bypassing the second protective layer 550 in the course of being discharged to the low-pressure outside.

FIG. 11B illustrates, compared with the embodiment illustrated in FIG. 11A, a second through-hole 581 formed in a partial region of a mold-releasing sheet 580 in order to further improve the remaining foam removal ratio. According to an embodiment, the second through-hole 581 may be formed in a position corresponding to the position in which the first through-hole 570 is formed, for example, around the periphery of the foam prevention member 560. According to the embodiment illustrated in FIG. 11B, not only can the remaining foam removal ratio be further improved, but the remaining foam discharge path can be shortened, thereby reducing the time to perform the vacuum compression process for foam removal.

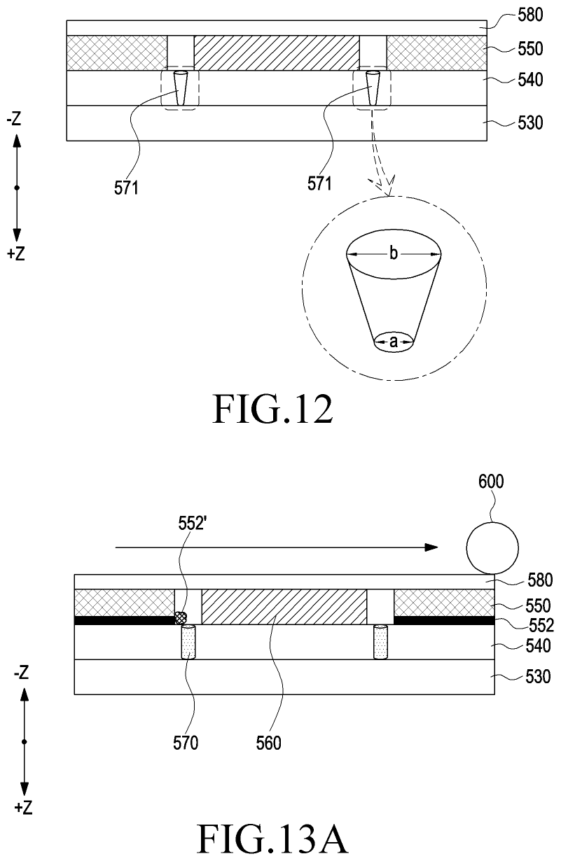

FIG. 12 is a diagram illustrating the shape of a through-hole 570 according to various embodiments disclosed in this document.

Referring to FIG. 12, the through-hole 570 may have a problem in that, the larger an in-hole is formed near the panel 530, the more the hole itself is visible to the outside. Therefore, an embodiment disclosed in this document may apply a through-hole 571 having a hopper shape having an in-hole with a small size a (or sectional area) and having an out-hole with a large size b (or sectional area) such that, while the in-hole is formed to have as small a size as possible, foam can be easily discharged.

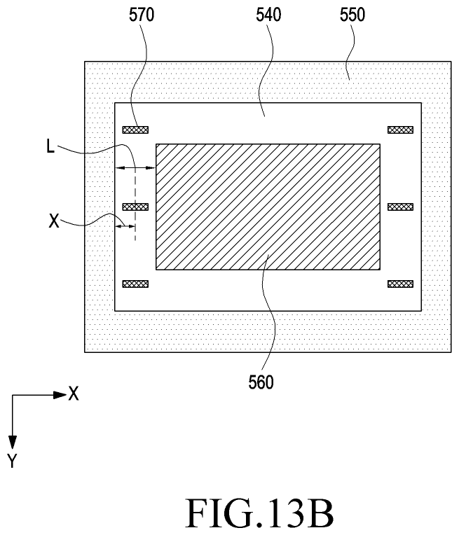

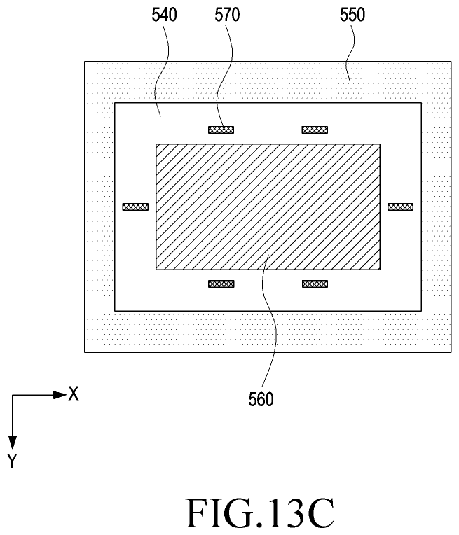

FIG. 13A is a schematic diagram illustrating impurities (for example, residues) occurring between a first protective layer 540 and a second protective layer 550 after a rolling process according to various embodiments disclosed in this document. FIG. 13A and FIG. 13B are top views illustrating a panel intermediate assembly having a through-hole 570 formed therein according to various embodiments disclosed in this document. FIG. 13B may illustrate the shape and disposition relation of a through-hole 570 according to an embodiment, and FIG. 13C may illustrate the disposition relation of a through-hole 570 according to an embodiment different from the embodiment in FIG. 13B.

Referring to FIG. 13A, if an adhesive layer 552 is formed between the first protective layer 540 and the second protective layer 550, the adhesive layer 552 may be pushed by a strong compression force, and remaining impurities (for example, residues 552') in the adhesive layer 552 may accordingly concentrate in the space formed by the first opening (for example, 545 in FIG. 8). This is referred to as a “residue pushing” phenomenon, which may block the through-hole 570 according to various embodiments disclosed in this document and thus adversely affect foam removal.

Referring to FIG. 13B, the position in which the through-hole 570 is formed by be configured in order to prevent the through-hole 570 clogging phenomenon illustrated in FIG. 13A. According to various embodiments, if the length between the foam prevention member 560 and the second protective layer 550 is “L” with reference to the rolling direction (for example, direction parallel to x-axis), the through-hole 570 may be formed such that the distance between the center thereof and the second protective layer 550 is equal to/larger than “L/2”, thereby preventing the through-hole 570 from being clogged due to the residue pushing phenomenon.

FIG. 13C illustrates an embodiment in which a panel intermediate assembly has multiple through-holes 570. As in the embodiment illustrated in FIG. 13B, some of the through-holes 570 may be formed along the long axis (for example, along x-axis) and the short axis (for example, along y-axis), respectively, between the periphery of the foam prevention member 560 and the second protective layer 550. According to an embodiment, if the rolling direction is parallel to the x-axis, more through-holes 570 may be formed along the long axis between the periphery of the foam prevention member 560 and the second protective layer 550 than through-holes 570 formed along the short axis between the periphery of the foam prevention member 560 and the second protective layer 550, thereby increasing the foam removal ratio.

According to various embodiments, multiple through-holes 570 may be provided. The through-holes 570 may have noncircular sections, and the section of each of the multiple through-holes 570 may have a long side facing in the same direction and a short side perpendicular to the long side. If the sections of the multiple through-holes 570 have long sides facing in the same direction, the direction in which the long sides face may be identical to the direction in which rollers proceed during a rolling process. Foam remaining on the rear side of the panel (for example, 430 in FIG. 4) may be effectively removed by forming the direction in which rollers proceed to be identical to the direction in which long sides of the through-holes 570 face. According to various embodiments, the through-holes 570 may be shaped such that the sections thereof are elongated along the long axis (for example, along x-axis), as illustrated in FIG. 13B and FIG. 13C. In addition, the sectional shape of the through-holes 570 is not limited to circular sectional shape illustrated in FIG. 10 and FIG. 12, and the same may have various shapes not illustrated in the drawings (for example, ellipses, rectangles, triangles, rhombuses).

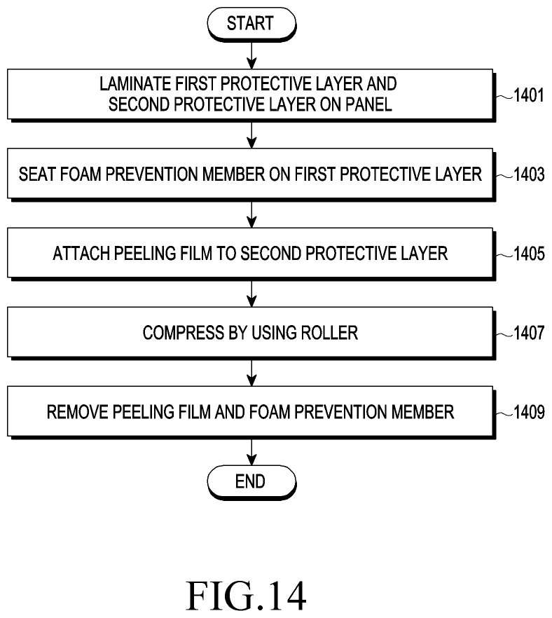

FIG. 14 is a flowchart of a method for manufacturing electronic device (for example, 100 in FIG. 1) according to various embodiments disclosed in this document.

The method for manufacturing an electronic device disclosed in FIG. 14 may be described in connection with a method for removing foam from a display panel.

Referring to FIG. 14, the method for manufacturing an electronic device according to various embodiments disclosed in this document may include an operation 1401 of laminating a first protective layer (for example, 540 in FIG. 11B) having at least one through-hole (for example, 570 in FIG. 11B) formed therein on a display panel (for example, 530 in FIG. 11B); an operation 1401 of laminating a second protective layer (for example, 550 in FIG. 4) having a first opening (for example, 454 in FIG. 4) formed therein so as to provide a space in which a sensor (for example, 490 in FIG. 4) is to be seated, on the first protective layer (for example, 540 in FIG. 11B); and an operation 1403 of seating a foam prevention member (for example, 560 in FIG. 11B) on the first protective layer (for example, 540 in FIG. 11B).

In relation to operation 1401, the size and position of the through-hole (for example, 570 in FIG. 11B) formed in the first protective layer (for example, 540 in FIG. 11B) may be determined in view of the size and position of the foam prevention member (for example, 560 in FIG. 11B) seated on the first protective layer (for example, 540 in FIG. 11B) in operation 1403. The foam prevention member (for example, 560 in FIG. 11B) may be provided as a kind of first foam prevention means, and the through-hole (for example, 570 in FIG. 11B) may be provided as a kind of second foam prevention means.

The method for manufacturing an electronic device according to various embodiments may include an operation 1405 of attaching a release film (for example, 580 in FIG. 11B) to the upper portion of the second protective layer; and an operation 1407 of compressing the upper portion of the release film (for example, 580 in FIG. 11B) by using a roller (for example, 600 in FIG. 11).

In relation to operation 1405, the release film (for example, 580 in FIG. 11B) may be made of the same material as the foam prevention member (for example, 560 in FIG. 11B). A second through-hole (for example, 581 in FIG. 11B) may be provided in the release film (for example, 580 in FIG. 11B) as a kind of third foam prevention means. According to an embodiment, the second through-hole (for example, 581 in FIG. 11B) may be formed in a position corresponding to the position in which the through-hole (for example, 570 in FIG. 11B) is formed. The description that the second through-hole is formed in a position corresponding to the position in which the through-hole of the first protective layer is formed may mean that the position of the second through-hole is determined such that remaining foam is discharged along the smallest path.

According to various embodiments, after the operation 1407 of compressing the upper portion of the release film by using the roller, a process of vacuum-compressing (autoclaving) the laminated structure including the panel (for example, 530 in FIG. 11B), the first protective layer (for example, 540 in FIG. 11B), and the second protective layer (for example, 550 in FIG. 11B). By vacuum-compressing the periphery of the laminated structure, foam can be removed from the laminated structure quickly and effectively.

The method for manufacturing an electronic device according to various embodiments may include an operation 1409 of removing the release film (for example, 580 in FIG. 11B) and the foam prevention member (for example, 560 in FIG. 11B) after operation 1407.

In relation to operation 1409, components such as a cover member (for example, 434 in FIG. 5) and a sensor (for example, 490 in FIG. 4) may be laminated/disposed in the position from which the foam prevention member has been removed, thereby forming a completed display assembly.

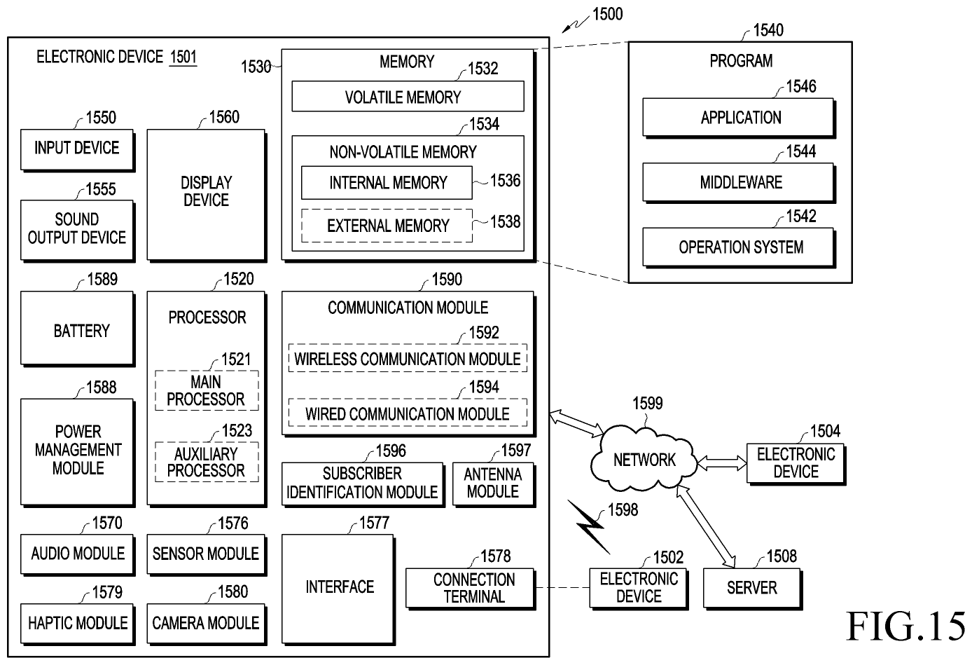

FIG. 15 is a block diagram illustrating an electronic device 1501 in a network environment 1500 according to various embodiments. Referring to FIG. 15, the electronic device 1501 in the network environment 1500 may communicate with an electronic device 1502 via a first network 1598 (e.g., a short-range wireless communication network), or an electronic device 1504 or a server 1508 via a second network 1599 (e.g., a long-range wireless communication network). According to an embodiment, the electronic device 1501 may communicate with the electronic device 1504 via the server 1508. According to an embodiment, the electronic device 1501 may include a processor 1520, memory 1530, an input device 1550, a sound output device 1555, a display device 1560, an audio module 1570, a sensor module 1576, an interface 1577, a haptic module 1579, a camera module 1580, a power management module 1588, a battery 1589, a communication module 1590, a subscriber identification module (SIM) 1596, or an antenna module 1597. In some embodiments, at least one (e.g., the display device 1560 or the camera module 1580) of the components may be omitted from the electronic device 1501, or one or more other components may be added in the electronic device 1501. In some embodiments, some of the components may be implemented as single integrated circuitry. For example, the sensor module 1576 (e.g., a fingerprint sensor, an iris sensor, or an illuminance sensor) may be implemented as embedded in the display device 1560 (e.g., a display).

The processor 1520 may execute, for example, software (e.g., a program 1540) to control at least one other component (e.g., a hardware or software component) of the electronic device 1501 coupled with the processor 1520, and may perform various data processing or computation. According to one embodiment, as at least part of the data processing or computation, the processor 1520 may load a command or data received from another component (e.g., the sensor module 1576 or the communication module 1590) in volatile memory 1532, process the command or the data stored in the volatile memory 1532, and store resulting data in non-volatile memory 1534. According to an embodiment, the processor 1520 may include a main processor 1521 (e.g., a central processing unit (CPU) or an application processor (AP)), and an auxiliary processor 1523 (e.g., a graphics processing unit (GPU), an image signal processor (ISP), a sensor hub processor, or a communication processor (CP)) that is operable independently from, or in conjunction with, the main processor 1521. Additionally or alternatively, the auxiliary processor 1523 may be adapted to consume less power than the main processor 1521, or to be specific to a specified function. The auxiliary processor 1523 may be implemented as separate from, or as part of the main processor 1521.

The auxiliary processor 1523 may control, for example, at least some of functions or states related to at least one component (e.g., the display device 1560, the sensor module 1576, or the communication module 1590) among the components of the electronic device 1501, instead of the main processor 1521 while the main processor 1521 is in an inactive (e.g., sleep) state, or together with the main processor 1521 while the main processor 1521 is in an active (e.g., executing an application) state. According to an embodiment, the auxiliary processor 1523 (e.g., an image signal processor or a communication processor) may be implemented as part of another component (e.g., the camera module 1580 or the communication module 1590) functionally related to the auxiliary processor 1523.

The memory 1530 may store various data used by at least one component (e.g., the processor 1520 or the sensor module 1576) of the electronic device 1501. The various data may include, for example, software (e.g., the program 1540) and input data or output data for a command related thereto. The memory 1530 may include the volatile memory 1532 or the non-volatile memory 1534.

The program 1540 may be stored in the memory 1530 as software, and may include, for example, an operating system (OS) 1542, middleware 1544, or an application 1546.

The input device 1550 may receive a command or data to be used by a component (e.g., the processor 1520) of the electronic device 1501, from the outside (e.g., a user) of the electronic device 1501. The input device 1550 may include, for example, a microphone, a mouse, or a keyboard.

The sound output device 1555 may output sound signals to the outside of the electronic device 1501. The sound output device 1555 may include, for example, a speaker or a receiver. The speaker may be used for general purposes, such as playing multimedia or playing record, and the receiver may be used for incoming calls. According to an embodiment, the receiver may be implemented as separate from, or as part of the speaker.

The display device 1560 may visually provide information to the outside (e.g., a user) of the electronic device 1501. The display device 1560 may include, for example, a display, a hologram device, or a projector and control circuitry to control a corresponding one of the display, hologram device, and projector. According to an embodiment, the display device 1560 may include touch circuitry adapted to detect a touch, or sensor circuitry (e.g., a pressure sensor) adapted to measure the intensity of force incurred by the touch.

The audio module 1570 may convert a sound into an electrical signal and vice versa. According to an embodiment, the audio module 1570 may obtain the sound via the input device 1550, or output the sound via the sound output device 1555 or an external electronic device (e.g., an electronic device 1502 (e.g., a speaker or a headphone)) directly or wirelessly coupled with the electronic device 1501.

The sensor module 1576 may detect an operational state (e.g., power or temperature) of the electronic device 1501 or an environmental state (e.g., a state of a user) external to the electronic device 1501, and then generate an electrical signal or data value corresponding to the detected state. According to an embodiment, the sensor module 1576 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 1577 may support one or more specified protocols to be used for the electronic device 1501 to be coupled with the external electronic device (e.g., the electronic device 1502) directly or wirelessly. According to an embodiment, the interface 1577 may include, for example, a high definition multimedia interface (HDMI), a universal serial bus (USB) interface, a secure digital (SD) card interface, or an audio interface.

A connecting terminal 1578 may include a connector via which the electronic device 1501 may be physically connected with the external electronic device (e.g., the electronic device 1502). According to an embodiment, the connecting terminal 1578 may include, for example, a HDMI connector, a USB connector, a SD card connector, or an audio connector (e.g., a headphone connector).

The haptic module 1579 may convert an electrical signal into a mechanical stimulus (e.g., a vibration or a movement) or electrical stimulus which may be recognized by a user via his tactile sensation or kinesthetic sensation. According to an embodiment, the haptic module 1579 may include, for example, a motor, a piezoelectric element, or an electric stimulator.

The camera module 1580 may capture a still image and moving images. According to an embodiment, the camera module 1580 may include one or more lenses, image sensors, image signal processors, or flashes.

The power management module 1588 may manage power supplied to the electronic device 1501. According to one embodiment, the power management module 1588 may be implemented as at least part of, for example, a power management integrated circuit (PMIC).

The battery 1589 may supply power to at least one component of the electronic device 1501. According to an embodiment, the battery 1589 may include, for example, a primary cell which is not rechargeable, a secondary cell which is rechargeable, or a fuel cell.

The communication module 1590 may support establishing a direct (e.g., wired) communication channel or a wireless communication channel between the electronic device 1501 and the external electronic device (e.g., the electronic device 1502, the electronic device 1504, or the server 1508) and performing communication via the established communication channel. The communication module 1590 may include one or more communication processors that are operable independently from the processor 1520 (e.g., the application processor (AP)) and support a direct (e.g., wired) communication or a wireless communication. According to an embodiment, the communication module 1590 may include a wireless communication module 1592 (e.g., a cellular communication module, a short-range wireless communication module, or a global navigation satellite system (GNSS) communication module) or a wired communication module 1594 (e.g., a local area network (LAN) communication module or a power line communication (PLC) module). A corresponding one of these communication modules may communicate with the external electronic device via the first network 1598 (e.g., a short-range communication network, such as Bluetooth™, wireless-fidelity (Wi-Fi) direct, or infrared data association (IrDA)) or the second network 1599 (e.g., a long-range communication network, such as a cellular network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 1592 may identify and authenticate the electronic device 1501 in a communication network, such as the first network 1598 or the second network 1599, using subscriber information (e.g., international mobile subscriber identity (IMSI)) stored in the subscriber identification module 1596.

The antenna module 1597 may transmit or receive a signal or power to or from the outside (e.g., the external electronic device) of the electronic device 1501. According to an embodiment, the antenna module 1597 may include one or more antennas, and at least one antenna appropriate for a communication scheme used in the communication network, such as the first network 1598 or the second network 1599, may be selected, for example, by the communication module 1590 from the one or more antennas. The signal or the power may then be transmitted or received between the communication module 1590 and the external electronic device via the selected at least one antenna.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 1501 and the external electronic device 1504 via the server 1508 coupled with the second network 1599. Each of the electronic devices 1502 and 1504 may be a device of a same type as, or a different type, from the electronic device 1501. According to an embodiment, all or some of operations to be executed at the electronic device 1501 may be executed at one or more of the external electronic devices 1502, 1504, or 1508. For example, if the electronic device 1501 should perform a function or a service automatically, or in response to a request from a user or another device, the electronic device 1501, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 1501. The electronic device 1501 may provide the outcome, with or without further processing of the outcome, as at least part of a reply to the request. To that end, a cloud computing, distributed computing, or client-server computing technology may be used, for example.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used herein, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 1540) including one or more instructions that are stored in a storage medium (e.g., internal memory 1536 or external memory 1538) that is readable by a machine (e.g., the electronic device 1501). For example, a processor (e.g., the processor 1520) of the machine (e.g., the electronic device 1501) may invoke at least one of the one or more instructions stored in the storage medium, and execute it. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities. According to various embodiments, one or more of the above-described components or operations may be omitted, or one or more other components or operations may be added. Alternatively or additionally, a plurality of components (e.g., modules or programs) may be integrated into a single component. In such a case, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

According to various embodiments disclosed in this document, there may be provided an electronic device (for example, 100 in FIG. 1) including: a housing including a first plate (for example, 410 in FIG. 4) and a second plate (for example, 420 in FIG. 4) facing away from the first plate; a display panel (for example, 430 in FIG. 4) disposed between the first plate and the second plate, the panel being visible through the first plate and including a first surface (for example, 431 in FIG. 4) oriented in a first direction (for example, +z in FIG. 4) so as to face the first plate and a second surface (for example, 432 in FIG. 4) oriented in a second direction (for example, −z in FIG. 4) opposite to the first direction so as to face the second plate; at least one substrate layer (for example, 441 in FIG. 4) disposed between the second surface and the second plate, the substrate layer overlapping at least a part of the panel when viewed from an upper surface (for example, 441 in FIG. 4) of the first plate; a cushion layer (for example, 451 in FIG. 4) disposed between the substrate layer and the second plate, the cushion layer including an opening (for example, 454 in FIG. 4) overlapping the panel when viewed from the upper surface of the first plate; a first adhesive layer (for example, 442 in FIG. 4) disposed, so as to make contact, between the second surface and the substrate layer; a second adhesive layer (for example, 443 in FIG. 4) disposed, so as to make contact, between the substrate layer and the cushion layer; a sensor (for example, 490 in FIG. 4) disposed in at least a part of the opening; and at least one through-hole (for example, 470 in FIG. 4) extending from the opening to the second surface via the second adhesive layer, the substrate layer, and the first adhesive layer.

According to various embodiments, the sensor may be a biometric sensor including a fingerprint sensor.

According to various embodiments, the substrate layer may include a substantially transparent first layer and an opaque second layer (for example, 444 in FIG. 4).

According to various embodiments, the second layer may be disposed between the first adhesive layer and the first layer.

According to various embodiments, the first layer may be disposed between the first adhesive layer and the second layer.

According to various embodiments, the first layer may include polyethylene terephthalate (PET).

According to various embodiments, the through-hole may be formed to extend toward the first direction.

According to various embodiments, the at least one through-hole may include multiple through-holes formed around the sensor when viewed from the upper surface of the first plate.

According to various embodiments, the opening may have a rectangular shape having a long side and a short side when viewed from the upper surface of the first plate, and the multiple through-holes may be configured such that, when viewed from the upper surface of the first plate, more through-holes are disposed along the long side than through-holes disposed along the short side.

According to various embodiments, the through-hole may have a noncircular section, and sections of the multiple through-holes may all have long sides facing in the same direction and short sides perpendicular to the long sides.

According to various embodiments, each through-hole may be formed to have a hopper shape as a whole.

According to various embodiments, the size of the in-hole of each through-hole may be formed to be smaller than the size of the out-hole thereof.

According to various embodiments, the opening may have a rectangular shape having a long side and a short side when viewed from the upper surface of the first plate, and the sectional shape of the out-hole of each through-hole may be elongated along the long side. According to various embodiments, each through-hole may have a diameter of 1 micrometer to 500 micrometers.

According to various embodiments disclosed in this document, there may be provided an electronic device (for example, 100 in FIG. 1) including: a housing including a first plate (for example, 410 in FIG. 6) and a second plate (for example, 420 in FIG. 6) facing away from the first plate; a touchscreen display panel (for example, 430 in FIG. 6) disposed between the first plate and the second plate, the panel being visible through the first plate and including a first surface (for example, 431 in FIG. 6) oriented in a first direction (for example, +z in FIG. 6) so as to face the first plate and a second surface (for example, 432 in FIG. 6) oriented in a second direction (for example, −z in FIG. 6) opposite to the first direction so as to face the second plate; at least one substrate layer (for example, 441 in FIG. 6) disposed between the second surface and the second plate, the substrate layer 441 overlapping at least a part of the panel when viewed from an upper surface (for example, 441 in FIG. 6) of the first plate; a cushion layer (for example, 450 in FIG. 6) disposed between the substrate layer and the second plate, the cushion layer (for example, 451 in FIG. 6) including a first opening (for example, 454 in FIG. 6) overlapping the panel when viewed from the upper surface of the first plate; a first adhesive layer (for example, 442 in FIG. 6) disposed, so as to make contact, between the second surface and the substrate layer; a second adhesive layer (for example, 443 in FIG. 6) disposed, so as to make contact, between the substrate layer and the cushion layer, the second adhesive layer including a second opening (for example, 445 in FIG. 6) overlapping the first opening when viewed from the upper surface of the first plate; a sensor (for example, 490 in FIG. 6) disposed in at least a part of the first opening; a third adhesive layer (for example, 443a in FIG. 6) disposed between the substrate layer and the sensor while filling at least a part of the second opening; and at least one through-hole (for example, 470 in FIG. 6) extending from the second opening to the second surface via the substrate layer and the first adhesive layer.

According to various embodiments, the third adhesive layer may be disposed on the same interface with the second adhesive layer, and may be made of a material different form the second adhesive layer.

According to various embodiments disclosed in this document, there may be provided a method for removing foam from a display panel of an electronic device, the method including: an operation (for example, 1401 in FIG. 14) of laminating a first protective layer (for example, 540 in FIG. 11B) having at least one through-hole (for example, 570 in FIG. 11B) formed therein on a display panel (for example, 530 in FIG. 11B); an operation (for example, 1401 in FIG. 14) of laminating a second protective layer (for example, 550 in FIG. 11B) having an opening formed therein so as to provide a space for sensor seating on the first protective layer; an operation (for example, 1403 in FIG. 14) of inserting a foam prevention member into the opening and seating the foam prevention member (for example, 560 in FIG. 11B) on a surface of the first protective layer; an operation (for example, 1405 in FIG. 14) of attaching a release film (for example, 580 in FIG. 11B) to an upper portion of the second protective layer; an operation (for example, 1407 in FIG. 14) of compressing an upper portion of the release film by using a roller (for example, 600 in FIG. 11B); and an operation (for example, 1409 in FIG. 14) of removing the release film and the foam prevention member.

According to various embodiments, the method may further include an operation of vacuum-compressing a laminated structure on which the panel, the first protective layer, and the second protective layer are laminated, after the operation of compressing the upper portion of the release film by using a roller.

According to various embodiments, in the operation of seating the foam prevention member on the first protective layer, the foam prevention member may have the same height as the height at which the second protective layer is formed.

According to various embodiments, multiple second through-holes may be formed in the release film.

According to various embodiments, the second through-holes may be formed in positions corresponding to an offset region in which the foam prevention member is not disposed.

1. An electronic device comprising:
a housing comprising a first plate and a second plate facing away from the first plate;
a display panel disposed between the first plate and the second plate, the panel being visible through the first plate and comprising a first surface oriented in a first direction so as to face the first plate and a seco surface oriented in a second direction opposite to the first direction so as to face the second plate;
at least one substrate layer disposed between the second surface and the second plate, the substrate layer overlapping at least a part of the panel when viewed from an upper surface of the first plate;
a cushion layer disposed between the substrate layer and the second plate, the cushion layer comprising an opening overlapping the panel when viewed from the upper surface of the first plate;
a first adhesive layer disposed between the second surface and the substrate layer, the first adhesive layer being contacted with the second surface and the substrate layer;
a second adhesive layer disposed between the substrate layer and the cushion layer, the second adhesive layer being contacted with the substrate layer and the cushion layer;
a sensor disposed in at least a part of the opening; and
at least one through-hole extending from the opening to the second surface via the second adhesive layer, the substrate layer, and the first adhesive layer.

2. The electronic device of claim 1, wherein the substrate layer comprises a substantially transparent first layer and an opaque second layer.

3. The electronic device of claim 2, wherein the second layer is disposed between the first adhesive layer and the first layer.

4. The electronic device of claim 2, wherein the first layer is disposed between the first adhesive layer and the second layer.

5. The electronic device of claim 2, wherein the first layer comprises polyethylene terephthalate (PET).

6. The electronic device of claim 1, wherein the through-hole is formed to extend toward the first direction.

7. The electronic device of claim 1, wherein the at least one through-hole comprises multiple through-holes formed around the sensor when viewed from the upper surface of the first plate.

8. The electronic device of claim 7, wherein the opening has a rectangular shape having a long side and a short side when viewed from the upper surface of the first plate, and
the multiple through-holes are configured such that, when viewed from the upper surface of the first plate, more through-holes are disposed along the long side than through-holes disposed along the short side.

9. The electronic device of claim 1, wherein the through-hole has a diameter of 1 micrometer to 500 micrometers.

10. The electronic device of claim 1, wherein the second adhesive layer comprises a second opening overlapping the opening when viewed from the upper surface of the first plate, and
the electronic device further comprises a third adhesive layer disposed, so as to make contact, between the substrate layer and the sensor while filling at least a part of the second opening.

11. A method for manufacturing an electronic device, the method comprising:
stacking a first protective layer including at least one through-hole formed therein on a display panel;
stacking a second protective layer including an opening formed therein so as to provide a space for sensor seating on the first protective layer;
inserting a foam prevention member into the opening and seating the foam prevention member on a surface of the first protective layer;
attaching a release film to an upper portion of the second protective layer;
compressing an upper portion of the release film by using a roller; and
removing the release film and the foam prevention member.

12. The method of claim 11, further comprising vacuum-compressing a laminated structure on which the panel, the first protective layer, and the second protective layer are laminated, after the compressing an upper portion of the release film by using a roller.

13. The method of claim 11, wherein, in the seating of the foam prevention member on the first protective layer, the foam prevention member has the same height as the height at which the second protective layer is formed.

14. The method of claim 13, wherein multiple second through-holes are formed in the release film.

15. The method of claim 14, wherein the second through-holes are formed in positions corresponding to an offset region in which the foam prevention member is not disposed on the first protective layer.
